(19) United States
(12) Patent Application Publication
(10) Pub. No.: US 2011/0030762 A1
(43) Pub. Date: Feb. 10, 2011

(54) ENERGY CONCENTRATION DEVICE OF UNITED REFLECTION WITH MULTILEVEL SOLAR CELL ARRAY

(75) Inventor: Young Hun Kim, Daejeongwangyeok-si (KR)

Correspondence Address: SEED INTELLECTUAL PROPERTY LAW GROUP PLLC, 701 FIFTH AVE, SUITE 5400, SEATTLE, WA, 98104, US

(73) Assignee: U.R. TECH CORPORATION, Chicago, IL (US)

(21) Appl. No.: 12/536,416

(22) Filed: Aug. 5, 2009

(51) Int. Cl. H01L 31/052

(52) U.S. Cl. 136/246

(57) ABSTRACT

The present invention relates to an energy concentration device of united reflection with multilevel solar cell array comprising: a housing and solar cell parts, which are multilevel arrayed inside or outside the housing in such a way that the part of collected sunlight is absorbed in each level and then the rest of unabsorbed sunlight is absorbed overall from multilevel of solar cells in the iterating process of reflecting sunlight on the surfaces of solar cell parts.

By the present invention, if an energy concentration device of united reflection with multilevel solar cell array is attached to the solar concentration device and so on, it is possible to attach to both fixed type and movable type. In the process of reflecting and absorbing sunlight continuously to maximise sunlight availability, solar cell parts are arrayed multilevel to improve the collecting efficiency. Furthermore, they can improve the effectiveness of the reflection of the collecting sunlight which is reflecting on the installed reflectors on the sides of the third solar cell part which is firstly collecting sunlight.

### BACKGROUND OF THE INVENTION

1. Field of the Invention

The present invention relates to an energy concentration device of united reflection with multilevel solar cell array, and more particularly, an energy concentration device of united reflection with multilevel solar cell array, which can get higher energy efficiency at the time of concentrating sunlight by arranging solar cells in a multilevel structure.

2. Description of the Related Art

Generally speaking, a solar energy generating equipment is a device which utilizes solar cells to transform sunlight into electric energy. At this time, the solar cell are formed of a PN junction semiconductor and the solar cells function to induce electric energy in the process of producing free electrons from sunlight.

On this occasion, for a solar energy generating equipment, a sunlight concentration device to integrate sunlight and then to irradiate sunlight onto the surface of solar cell parts is used. The solar accumulation rate of the concentration device is directly related to the energy efficiency of the generating equipment, and it is proportional to the area of a concentrating focus lens for overlapping sunlight installed in front of the solar cell.

Furthermore, sunlight is regarded not to contaminate the environment and has no limitation to use so it is the most preferred one of substitute energies. In addition to its ability to generate electric power energy using solar cells, it is currently in the process of wide research and commercialisation to provide hot water by using the solar energy and to eradicate various types of germs.

In particular, in the case of the solar energy concentration device among devices using various sunlight, it is to concentrate sunlight on a spot, and then it is to produce electric energy or heat energy using the solar cell array. A practical or economical product of the sunlight concentration device is made by the amount and the ratio of concentrating sunlight.

Here, the sunlight concentrating device is classified from a fixed type which is fixed regardless of the movement of the sun, and the other one of a moving type following the movement of the sun track.

However, the existing concentrating device of sunlight, which is not drawn in the drawings, has various problems. The concentrating efficiency of the existing sunlight concentrating device is limited because in the process of transforming sunlight into the energy through the concentrating lens, sunlight is only absorbed into uniformly shaped solar cells therefore the rest of the uncollected sunlight is not utilised, being reflected into the air.

### SUMMARY OF THE INVENTION

The present invention is conceived to solve the aforementioned problems of the existing concentration devices. The object of the present invention is to provide an energy concentration device of united reflection with multilevel solar cell array, when it is attached to the solar concentration device. It is possible to attach to either fixed type or movable type of a solar concentration device. To maximise the availability of sunlight, the solar cells are arrayed multilevel to enhance the concentration efficiency in the process of reflecting and absorbing sunlight continuously.

Another objective of the present invention is to provide an energy concentration device of united reflection with multilevel solar cell array, which improves the effectiveness of the reflection of the collected sunlight which is reflecting on the reflection surfaces of the installed reflectors on the sides of a third solar cell which is firstly collecting sunlight.

According to an aspect of the present invention for achieving the mentioned objective, the present invention comprises a housing and solar cell parts, which are multilevel arrayed inside or outside the housing in such a way that part of concentrated sunlight is absorbed through each of the multilevel solar cells and the rest of sunlight is absorbed overall in the iterating process of reflecting sunlight on the multilevel solar cells.

In addition, in the aspect of the present invention, the above mentioned solar cell parts have a special feature of locating at least two levels.

In addition, in the aspect of the present invention, the solar cell parts of upper levels, which the concentrated sunlight passes through, have a special feature of forming a hole, except the lowest level of the solar cell part.

In accordance with another aspect of the present invention, the above mentioned solar cell array has a special feature of installing reflectors on the sides of the solar cell part, attached in the lowest level of the housing, which is firstly sunlight is collected through among the solar cell parts.

In addition, in the aspect of the present invention, each the above mentioned solar cell array has a special feature of absorbing sunlight from both sides of the arrayed solar cell parts.

3. The Effect of the Invention

Such an energy concentration device of united reflection with multilevel solar cell array, when it is attached to the solar concentration device, it is possible to attach to both fixed type and movable type. To maximise the sunlight availability in the process of reflecting and absorbing sunlight continuously, the solar cell parts are arrayed multilevel. They are also improving the collection efficiency. They can improve the reflecting effectiveness of the collected sunlight reflecting on the reflection surface, installing reflectors on the sides of the number 3 solar cell part which is firstly collecting sunlight.

### BRIEF DESCRIPTION OF THE DRAWINGS

FIG. 1 is a view schematically illustrating the concept of an energy concentration device of united reflection with multilevel solar cell array according to the present invention;

FIG. 2 is a cross-sectional view illustrating the above energy concentration device of united reflection with multilevel solar cell array_according to the present invention;

FIG. 3 is a view schematically illustrating the concept of an energy concentration device of united reflection with multilevel solar cell array attached the reflectors on the sides of the number 3 solar cell according to the present invention;

### THE DETAILED DESCRIPTION OF THE INVENTION

Hereinafter, a specific configuration and operation of the present invention will be described in detail with reference to the accompanying drawings.

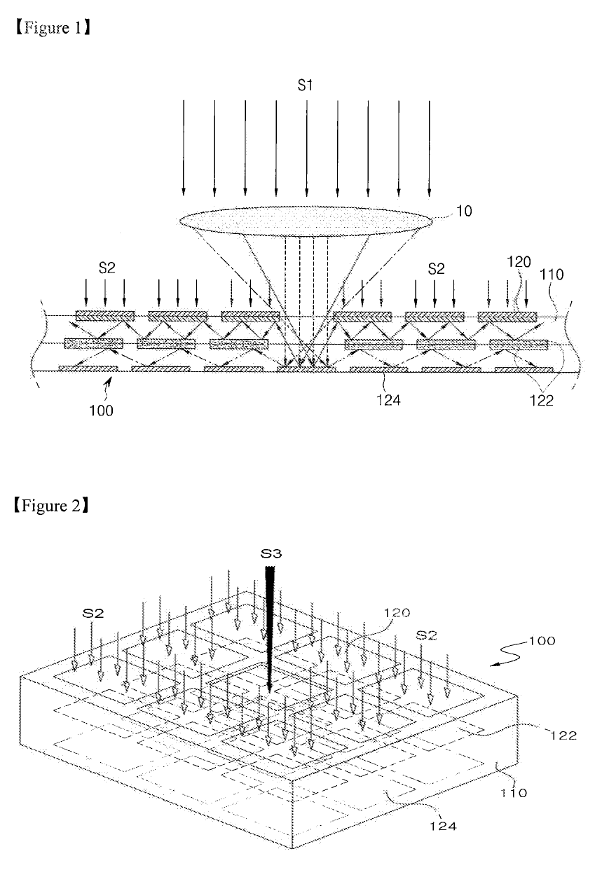

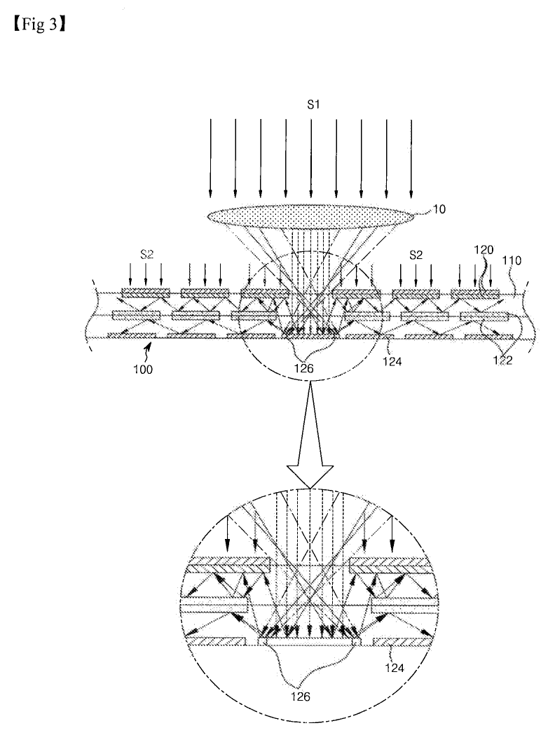

Referring to FIGS. 1 to 2, an energy concentration device of united reflection with multilevel solar cell array according to the desirable present invention comprises a concentration lens 10, a housing 110, solar cells parts 120, 122, 124, the solar cell parts can be arrayed at least two levels to form multilevel. The present example shows that it is comprised of the three levels of the first, second and third solar cell parts 120, 122, 124.

Moreover, according to the present invention, an energy concentration device of united reflection with multilevel solar cell array 100 can install both a fixed type which is fixed regardless the movement of the sun and a movable type which is following after the movement of the sun. An example of the adoption to the concentration device is illustrated. It is possible to attach to various types of other devices that are needed to collecting sunlight.

On the other hand, the first, second and third solar cell parts 120,122,124 can absorb the sunlight on both side of the surfaces, more desirable, except the third solar cell part 124 of the most lowest level, the remaining first and second solar cells parts 120, 122 can absorb the concentrated sunlight S3 on both sides of the cell surfaces.

The solar cell parts 120,122,124 are installed inside of the above mentioned housing 110 with multilevel. Sunlight S1 is concentrated onto the number 3 solar cell part 124 through the concentrating lens 10 installed above the housing 110.

On this occasion, a hole can be formed to pass through the sunlight S3 concentrated on the upper part of the housing 110. The solar cell array is comprised of the first, second and third solar cell parts 120,122,124. A hole is formed in which collected sunlight can pass through at the first and second solar cell parts 120,122, except the third solar cell part 124. The solar cell parts are located vertically to the hole of the housing 110 and through the hole the concentrated sunlight S3 is firstly transmitted to the third solar cell part 124. Moreover, the above hole can increase or decrease in the diameter selectively considering the incident angle and the reflection angle.

Then, the solar cell parts can be installed inside walls of the above mentioned housing 110.

The first solar cell part 120 is arrayed to the upper outer wall of the housing 110, which absorbs overall sunlight S2 which is not yet absorbed. Concentrated sunlight S3 is firstly absorbed by the third solar cell part 124 through the hole at the first and second solar cell parts 120, 122. The first and second solar cell parts 120, 122 are installed nearby to absorb the rest of sunlight in the process of reflecting on these parts.

The first solar cell part 120 which is made of a pair of solar cell units with the upper part and the lower part symmetrically is to be installed the second solar cell parts 122. The second solar cell part 122 which is made a pair of solar cell units with the upper part and the lower part symmetrically is to be installed between the first and third solar cell parts 120, 124. Concentrated sunlight S3 is firstly absorbed through the number 3 solar cell part 124, the rest of sunlight reflects on and absorbs respectively to the solar cell parts 120,122,124.

At this time, the first and second solar cell parts 120, 122 can be installed to absorb sunlight through both the upper surface and the below surface of each solar cell parts.

The third solar cell part 124 is arrayed on the lower side of the second solar cell part 122, also on inside wall of the housing 110, part of the concentrated sunlight S3 is firstly absorbed through the third solar cell part 124. Then the rest of the sunlight is absorbed overall to the first, second and third solar cell parts 120, 122, 124 in the process of reflecting on the lower side of the first and second solar cell parts 120, 122.

On the other hand, as shown on FIG. 3, among the third solar cell part 124, the firstly concentrated sunlight S3 passed through the hole of the first and second solar cell parts 120, 122, is absorbed to the third solar cell part 124 located in the centre. Then mirror reflectors 126 are installed on the side walls of the third solar cell part 124 which is firstly collecting sunlight.

Here, as the above mentioned reflectors 126 are installed on the side walls of the number 3 solar cell part 124 which is sunlight is firstly concentrated through the concentrating lens 10, and then the concentrated sunlight S3 through the concentrating lens 10 is absorbed by the third solar cell part 124 located on the centre. Then, part of the light is absorbed to the third solar cell part 124. Not only the rest of uncollected sunlight but also the concentrated sunlight S3 reflecting on the surface of the reflectors 126 improve the reflection efficiency of the first and second solar cell parts 120,122 which is located on the opposite sides of the reflectors.

Therefore, according to the present invention, from the energy concentration device of united reflection with multilevel solar cell array 100, the process of concentration is such as; first of all, sunlight S1 is collected by concentrating lens 10. Then the concentrated sunlight S3 is emitted to the inside of the hole of the solar cell array housing 110. The rest uncollected of sunlight S2 is collected overall by the number 1 solar cell part 120 which is arrayed on the upper side of the housing 110.

On this occasion, the concentrated sunlight S3 is firstly and partly absorbed onto the surface of the third solar cell part 124 through the hole of the first and second solar cell parts 120,122. Then the rest of sunlight reflex on the solar cell parts 120,122 respectively and then it is absorbed to the whole surfaces of the first, second and third solar cell parts 120,122,124.

Eventually, as the first, second and third solar cell parts 120,122,124 are arrayed with multilevel, the concentrated sunlight S3 is firstly absorbed and then the rest of uncollected sunlight can be usable to the maximum, the collecting efficiency of sunlight improves in the iterating processes of the sunlight reflection and absorption.

The aforementioned detailed explanation of the present invention referring to the desirable examples, the protection area of the present invention is not limited to the above examples. The people who have the common knowledge of this technology field can understand that the present invention can be modified or changed in various ways as long as the modification does not exceed the principle and technical field of the invention.

What is claimed is:

1. An energy concentration device of united reflection with multilevel solar cell array, comprising:
a housing, and solar cell parts which are multilevel arrayed inside or outside the housing in such a way that the part of concentrated sunlight is absorbed through each of the multilevel solar cell parts and the rest of sunlight is absorbed overall in the iterating process of reflecting sunlight onto the multilevel solar cell parts.

2. The energy concentration device as claimed in claim 1, wherein the solar cell parts are located at least two levels.

3. The energy concentration device as claimed in claim 2, wherein the upper solar cell parts which are located in the upper levels of the housing are provided with a hole in which the concentrated sunlight pass through, except the lowest level of the solar cell part.

4. The energy concentration device as claimed in claim 2, wherein among the solar cell parts, reflectors are installed on the side walls of the solar cell part mounted to the lowest level which is firstly sunlight is collected.

5. The energy concentration device as claimed in claim 1, wherein the solar cell parts absorb sunlight from both sides of the surfaces of paired solar cell parts.
